(19) United States
(12) Patent Application Publication
(10) Pub. No.: US 2026/0022477 A1
(43) Pub. Date: Jan. 22, 2026

(54) METHOD FOR ELECTROCHEMICAL WATER SPLITTING

(71) Applicant: KING FAHD UNIVERSITY OF PETROLEUM AND MINERALS, Dhahran (SA)

(72) Inventors: Muhammad Ali EHSAN, Dhahran (SA); Abuzar KHAN, Dhahran (SA); Abbas Saeed HAKEEM, Dhahran (SA)

(73) Assignee: KING FAHD UNIVERSITY OF PETROLEUM AND MINERALS, Dhahran (SA)

(21) Appl. No.: 19/340,971

(22) Filed: Sep. 26, 2025

Related U.S. Application Data
(62) Division of application No. 18/183,760, filed on Mar. 14, 2023.

(51) Int. Cl. C25B 11/052; C23C 16/40; C23C 16/448; C25B 1/04; C25B 9/17; C25B 11/031; C25B 11/061; C25B 11/077

(52) U.S. Cl. CPC C25B 11/052; C23C 16/405; C23C 16/4486; C25B 1/04; C25B 9/17; C25B 11/031; C25B 11/061; C25B 11/077

(57) ABSTRACT

A vanadium oxide-based electrode for electrochemical water splitting that includes metallic substrate and a layer of particles of a vanadium oxide composite at least partially covering a surface of the metallic substrate. The particles of the vanadium oxide composite are in the form of nanobeads having an average particle size of 50 to 400 nm. A method of making the electrode.

### STATEMENT OF ACKNOWLEDGEMENT

This research was supported by the Deanship of Scientific Research (DSR) at King Fahd University of Petroleum and Minerals (KFUPM) under the project DF191048.

### BACKGROUND

### Technical Field

The present disclosure is directed to an electrode, particularly a vanadium oxide (VOₓ)-based electrode for electrochemical water splitting and a method of preparation thereof.

### Description of Related Art

The “background” description provided herein is to present the context of the disclosure generally. Work of the presently named inventors, to the extent it is described in this background section, as well as aspects of the description that may not otherwise qualify as prior art at the time of filing, are neither expressly nor impliedly admitted as prior art against the present invention. Excessive burning of fossil fuels and the subsequent adverse impact on our environment are quite evident almost daily. Therefore, the energy transition toward greener or safer alternatives is discussed and strategized in many countries [Kovač, A.; Paranos, M.; Marciuš, D., Hydrogen in energy transition: A review. International Journal of Hydrogen Energy 2021, 46 (16), 10016-10035 and Capurso, T.; Stefanizzi, M.; Torresi, M.; Camporeale, S., Perspective of the role of hydrogen in the 21st-century energy transition. Energy Conversion and Management 2022, 251, 114898]. The energy transition aims to gradually shift the energy vectors from conventional fossil fuels resources to renewable energy sources, such as wind, solar, and geothermal, etc [Shojaeddini, E.; Naimoli, S.; Ladislaw, S.; Bazilian, M., Oil and gas company strategies regarding the energy transition. Progress in Energy 2019, 1 (1), 012001]. However, most of these renewable resources suffer from intermittency and unsustainability issues. In this regard, hydrogen is considered a renewable and sustainable energy carrier if it is produced in green form i.e., electrocatalytic water splitting yielding net zero CO₂ emission, and it is environmentally benign [Abdin, Z.; Zafaranloo, A.; Rafiee, A.; Mérida, W.; Lipiński, W.; Khalilpour, K. R., Hydrogen as an energy vector. Renewable and sustainable energy reviews 2020, 120, 109620 and Yu, M.; Wang, K.; Vredenburg, H., Insights into low-carbon hydrogen production methods: Green, blue and aqua hydrogen. International Journal of Hydrogen Energy 2021, 46 (41), 21261-21273].

Conventionally, electrocatalytic water splitting technology is sensitive to the capacity of an electrocatalyst, and hence, the energy conversion efficiency of the process largely depends on the fundamental improvements in the activity of the electrocatalyst being studied [You, B.; Sun, Y., Innovative strategies for electrocatalytic water splitting. Accounts of chemical research 2018, 51 (7), 1571-1580]. This leads to efforts in designing and subsequent fabrication of new catalytic materials that are efficient, scalable, and stable [Charles, V.; Anumah, A. O.; Adegoke, K. A.; Adesina, M. O.; Ebuka, I. P.; Gaya, N. A.; Ogwuche, S.; Yakubu, M. O., Progress and challenges pertaining to the earthly-abundant electrocatalytic materials for oxygen evolution reaction. Sustainable Materials and Technologies 2021, 28, e00252 and Li, Y.; Zhou, L.; Guo, S., Noble metal-free electrocatalytic materials for water splitting in alkaline electrolyte EnergyChem 2021, 3 (2), 100053].

Yet conventionally, electrochemical water splitting includes two steps, an oxygen evolution reaction (OER) at an anode and a hydrogen evolution reaction (HER) at a cathode. Hydrogen-based fuel production via the electrochemical water splitting is mainly hindered at the industrial scale due to the sluggish four-electron transfer process involved in the OER [Chandrasekaran, S.; Ma, D.; Ge, Y.; Deng, L.; Bowen, C.; Roscow, J.; Zhang, Y.; Lin, Z.; Misra, R.; Li, J., Electronic structure engineering on two-dimensional (2D) electrocatalytic materials for oxygen reduction, oxygen evolution, and hydrogen evolution reactions. Nano Energy 2020, 77, 105080 and Suen, N.-T.; Hung, S.-F.; Quan, Q.; Zhang, N.; Xu, Y.-J.; Chen, H. M., Electrocatalysis for the oxygen evolution reaction: recent development and future perspectives. Chemical Society Reviews 2017, 46 (2), 337-365]. The hindered results put forward the ultimate desire to develop inexpensive OER catalysts that may reduce the over-potential and increase the efficiency of the overall system [Gonçalves, J. M.; Matias, T. A.; Toledo, K. C.; Araki, K., Electrocatalytic materials design for oxygen evolution reaction. In Advances in Inorganic Chemistry, Elsevier: 2019; Vol. 74, pp 241-303]. Conventional Ruthenium (Ru) and Iridium (Ir) based electrocatalysts possess stable OER performance under acidic and alkaline conditions. However, these costly and scarce elements of the catalysts limit their potential for large-scale deployment [Wang, F.; Tian, F.; Deng, Y.; Yang, L.; Zhang, H.; Zhao, D.; Li, B.; Zhang, X.; Fan, L., Cluster-based multifunctional copper (II) organic framework as a photocatalyst in the degradation of organic dye and as an electrocatalyst for overall water splitting. Crystal Growth & Design 2021, 21 (7), 4242-4248]. Therefore, there is a critical need to develop low cost, earth-abundant transition metal-based effective electrocatalytic water splitting.

Active and durable transition metal-based catalytic systems have been reported [Wang, Y.; Zheng, X.; Wang, D., Design concept for electrocatalysts. Nano Research 2021, 1-23 and Linnemann, J.; Kanokkanchana, K.; Tschulik, K., Design strategies for electrocatalysts from an electrochemist's perspective. ACS Catalysis 2021, 11 (9), 5318-5346]. However, these catalysts showed inferior performance relative to the noble metal-based catalysts. Therefore, it is clear that more effort is still required to improve the catalytic performance, which may be achieved by advanced preparation methods, inducing certain features in the catalyst, etc., while keeping an effective cost.

Different monometallic, bimetallic, and trimetallic-based catalysts, non-precious transition metals, such as nickel (Ni), cobalt (Co), and iron (Fe), etc., and their compounds have been reported as active catalysts in the OER process [Liang, H.; Xu, M.; Asselin, E., Corrosion of monometallic iron- and nickel-based electrocatalysts for the alkaline oxygen evolution reaction: A review. Journal of Power Sources 2021, 510, 230387; Jiang, J.; Zhang, Y.-J.; Zhu, X.-J.; Lu, S.; Long, L.-L.; Chen, J.-J., Nanostructured metallic FeNi2S4 with reconstruction to generate FeNi-based oxide as a highly-efficient oxygen evolution electrocatalyst. Nano Energy 2021, 81, 105619 and Jiang, S.; Zhu, L.; Yang, Z.; Wang, Y., Self-supported hierarchical porous FeNiCo-based amorphous alloys as high-efficiency bifunctional electrocatalysts toward overall water splitting. International Journal of Hydrogen Energy 2021, 46 (74), 36731-36741].

Vanadium (V) is one of the transition metals with multiple oxidation states, from (+2) to (+5), thus producing various crystalline phases [Shen, T. F.-R.; Lai, M.-H.; Yang, T. C.-K.; Fu, I.-P.; Liang, N.-Y.; Chen, W.-T., Photocatalytic production of hydrogen by vanadium oxides under visible light irradiation. Journal of the Taiwan Institute of Chemical Engineers 2012, 43 (1), 95-Vanadium oxides (VOₓ) are studied as a cathode in lithium batteries due to their electrochemical properties, high specific capacity, and energy density [Shen, T. F.-R.; Lai, M.-H.; Yang, T. C.-K.; Fu, I.-P.; Liang, N.-Y.; Chen, W.-T., Photocatalytic production of hydrogen by vanadium oxides under visible light irradiation. Journal of the Taiwan Institute of Chemical Engineers 2012, 43 (1), 95-101]. The vanadium-based materials have the capability to develop ionic and molecular interactions, producing better electrocatalytic and/or photocatalytic materials for both the OER/HER [Liardet, L.; Hu, X., Amorphous cobalt vanadium oxide as a highly active electrocatalyst for oxygen evolution. ACS catalysis 2018, 8 (1), 644-650; Merle, G.; Abrahams, I.; Barralet, J., Powerful amorphous mixed metal catalyst for efficient water-oxidation. Materials today energy 2018, 9, 247-253 and Akhoondi, A.; Feleni, U.; Bethi, B.; Idris, A. O.; Hojjati-Najafabadi, A., Advances in metal-based vanadate compound photocatalysts: synthesis, properties and applications. Synthesis and Sintering 2021, 1 (3), 151-168].

There has been a growing trend to develop composite catalyst systems that provide improved surface area, electric conductivity, and better performance. A similar approach may be taken to improve the OER activity of VOx-based electrocatalysts through synergetic interactions with other materials. By taking advantage of the synergistic and additive properties of mixed oxides that exhibit superior electrocatalytic behavior. Several metal oxides (nickel, iron, and cobalt) were incorporated with VOₓ to obtain bimetallic and trimetallic oxides. The incorporation of vanadium resulted in a positive synergistic effect that significantly increased their OER activity [Liardet, L.; Hu, X., Amorphous cobalt vanadium oxide as a highly active electrocatalyst for oxygen evolution. ACS catalysis 2018, 8 (1), 644-650; Merle, G.; Ehsan, M. A.; Hakeem, A. S.; Sharif, M.; Rehman, A., Direct deposition of amorphous cobalt-vanadium mixed oxide films for electrocatalytic water oxidation. ACS omega 2019, 4 (7), 12671-12679 and Babar, N.-U.-A.; Hakeem, A. S.; Ehsan, M. A., Direct Fabrication of Nanoscale NiVOₓ Electrocatalysts over Nickel Foam for a High-Performance Oxygen Evolution Reaction. ACS Applied Energy Materials 2022, 5 (4), 4318-4328].

A systematic approach toward a better electrode design that may have nanoscale features, and with many electroactive sites may reduce the contact resistance among nanoparticles within the catalytic films. Aerosol-assisted chemical vapor (AACVD) deposition process can be used to make catalytic thin films. However, current techniques do not offer a sustainable and cost-effective method for making a catalyst for hydrogen production via electrocatalytic water splitting that allows control of surface morphology and thickness. Therefore, there is an unmet need for catalysts and methods of making catalysts that provide oxygen evolution reaction (OER) performance at high rates.

### SUMMARY

In an exemplary embodiment, an electrode is described. The electrode includes a metallic substrate. The electrode further includes a layer of particles of a vanadium oxide (VOₓ) composite at least partially covering a surface of the metallic substrate. In some embodiments, the particles of the VOₓ composite are in the form of nanobeads having an average particle size of 50 to 400 nanometers (nm).

In some embodiments, the metallic substrate is at least one metal foam selected from the group including an aluminum foam, a nickel foam, a titanium foam, a titanium alloy foam, an aluminum alloy foam, a magnesium alloy foam, a nickel alloy foam, and a steel foam.

In some embodiments, the vanadium oxide composite includes vanadium monoxide (VO), vanadium trioxide (V₂O₃), vanadium dioxide (VO₂), and vanadium pentoxide (V₂O₅), and the metallic substrate is a nickel foam (NiF).

In some embodiments, the vanadium oxide composite has a particle size in a range of 100 to 200 nm.

In some embodiments, the metallic substrate is a nickel foam. In some embodiments, a combination of the vanadium oxide composite and the nickel foam has a synergistic effect, resulting in improved electrocatalytic performance of the electrode.

In some embodiments, the electrode has a current density of 800 to 1200 milliamperes per square centimeters (mA/cm²) at a potential of 1.7 volts reversible hydrogen electrode (V_{RHE}). In some embodiments, the electrode has a Tafel slope of 50 to 90 millivolts per decade (mV/decade).

In some embodiments, a method of making the electrode includes mixing and dissolving the vanadium oxide precursor in a solvent to form a solution. The method further includes aerosolizing the solution to form an aerosol containing the vanadium oxide precursor. The method also includes placing the metallic substrate in a heating chamber, and passing the aerosol through the heating chamber with the aid of a carrier gas. In some embodiments, the carrier gas includes nitrogen. In some embodiments, the metallic substrate is in direct contact with the aerosol. Additionally, the method includes heating the metallic substrate in the heating chamber to form the electrode having the layer of the vanadium oxide composite at least partially covered on the surface of the metallic substrate.

In some embodiments, the vanadium oxide precursor is at least one selected from the group consisting of ammonium vanadate, vanadyl oxalate, vanadium pentoxide, vanadium monoethanolamine, vanadium chloride, vanadium trichloride oxide, vanadyl sulfate, vanadium antimonate, antimony vanadate, vanadium oxyacetylacetonate, vanadium oxyacetate, vanadium oxyhalide, and vanadium oxytriisopropoxide.

In some embodiments, the vanadium oxide precursor is present in the solution at a concentration of 0.01 to 0.1 Molarity (M).

In some embodiments, the solvent is at least one selected from the group consisting of a ketone solvent, an ester solvent, an alcohol solvent, an amide solvent, and an ether solvent.

In some embodiments, the solvent is the alcohol solvent. In some embodiments, the alcohol solvent is at least one selected from the group consisting of methanol, ethanol, n-propanol, and isopropanol.

In some embodiments, the aerosol is passed through the heating chamber at a rate of 80 to 120 cubic centimeters per minute (cm³/min) with the aid of the carrier gas.

In some embodiments, the aerosolizing is performed on the aerosol generator including a fluid chamber having a housing inlet, a housing outlet, and a vent. The aerosol generator also includes a vibrating element operably coupled to the support plate for generating the aerosol. In some embodiments, the solution is introduced into the fluid chamber via the housing inlet. In some embodiments, the fluid chamber is in fluid communication with the heating chamber via the housing outlet. In some embodiments, the carrier gas is introduced into the fluid chamber via the vent, thereby carrying the aerosol into the heating chamber.

In some embodiments, the heating is performed at a temperature of 400 to 600 degrees centigrade (° C.) for an appropriate amount of time.

In some embodiments, at least a portion of the vanadium oxide precursor is decomposed to generate the vanadium oxide composite during the heating.

In some embodiments, the metallic substrate is a nickel foam (NiF) having a porous structure.

In another exemplary embodiment, an electrochemical cell is described. The electrochemical cell includes the electrode, a counter electrode, and an electrolyte in contact with both electrodes.

In some embodiments, the electrolyte includes an aqueous solution of a base at a concentration of 0.1 to 3 M.

In some embodiments, the base is at least one selected from the group consisting of sodium hydroxide (NaOH), potassium hydroxide (KOH), lithium hydroxide (LiOH), barium hydroxide (Ba(OH)₂), and calcium hydroxide (Ca(OH)₂).

In yet another embodiment, a method for an electrochemical water splitting is described. The method includes applying a potential between the electrodes in the electrochemical cell to form hydrogen and oxygen and separately collecting H₂-enriched gas and O₂-enriched gas.

The foregoing general description of the illustrative present disclosure and the following The detailed description thereof are merely exemplary aspects of the teachings of this disclosure and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1 is a schematic flow diagram of a method of making an electrode, according to certain embodiments;

FIG. 2 is a schematic flow diagram depicting a method for an electrochemical water splitting, according to certain embodiments;

FIG. 3 illustrates an X-ray diffraction (XRD) pattern of vanadium oxide (VOₓ) thin films deposited on a non-crystalline plain glass substrate at 475 degrees centigrade (° C.) for a deposition time of 30 minutes (min) (VOₓ-30) and 60 min (VOₓ-30), according to certain embodiments;

FIG. 4A illustrates a scanning electron microscopy (SEM) image of the VOₓ thin film deposited on a nickel foam (NiF) substrate for 30 min (VOₓ/NiF-30 catalyst), according to certain embodiments;

FIG. 4B illustrates a SEM image of the VOₓ thin film deposited on the NiF substrate for 60 min (VOₓ/NiF-60 catalyst), according to certain embodiments;

FIG. 4C illustrates a SEM image of the VOₓ thin film deposited on the NiF substrate for 30 min in high magnification (VOₓ/NiF-30 catalyst), according to certain embodiments;

FIG. 4D illustrates a SEM image of the VOₓ thin film deposited on the NiF substrate for 60 min in high magnification (VOₓ/NiF-60 catalyst), according to certain embodiments;

FIG. 5A illustrates an X-ray photoelectron spectroscopy (XPS) survey scan spectrum of the VOₓ-30 catalyst, according to certain embodiments;

FIG. 5B illustrates an XPS survey scan spectrum of the VOₓ-30 catalyst with a high-resolution deconvoluted spectrum of V2p and O1s, according to certain embodiments;

FIG. 6A illustrates cyclic voltammetry (CV) curves (1st and 50th cyclic) of the VOₓ/NiF-30 catalyst recorded at a scan rate of 50 millivolts per second (mV/s) in 1.0 Molarity (M) potassium hydroxide (KOH) electrolyte solution, according to certain embodiments;

FIG. 6B illustrates CV curves (1st and 50th cyclic) of the VOₓ/NiF-60 catalyst recorded at a scan rate of 50 mV/s in 1.0 M KOH electrolyte solution, according to certain embodiments;

FIG. 6C illustrates CV curves (1st and 50th cyclic) of bare NiF recorded at a scan rate of 50 mV/s in 1.0 M KOH electrolyte solution, according to certain embodiments;

FIG. 7A illustrates linear sweep voltammetry (LSV) curves for the VOₓ/NiF-30 catalyst obtained at a scan rate of 5 mV/s in 1.0 M KOH electrolyte solution, according to certain embodiments;

FIG. 7B illustrates an enlarged view of the LSV curves for the VOₓ/NiF-30 catalyst obtained at a scan rate of 5 mV/s in 1.0 M KOH electrolyte solution, according to certain embodiments;

FIG. 7C illustrates an onset overpotential and peak current density values for the VOₓ/NiF-30, VOX/NiF-60, and the bare NiF electrodes extracted from respective LSV profiles, according to certain embodiments;

FIG. 7D illustrates a comparative overpotential plot result of study with some of conventional benchmarks in the field., according to certain embodiments;

FIG. 8A illustrates a Tafel plot and corresponding Tafel values for the bare NiF electrode, and the VOₓ catalysts, according to certain embodiments;

FIG. 8B illustrates Nyquist plots for the VOₓ-30, and the VOₓ-60 samples, according to certain embodiments;

FIG. 8C is a plot depicting the effect of time on the stability of the VOₓ-30 catalyst (long-term stability test), according to certain embodiments; and

FIG. 8D illustrates comparative LSVs before and after long-term stability tests for the VOₓ-30 catalysts, according to certain embodiments.

### DETAILED DESCRIPTION

In the drawings, reference numerals designate identical or corresponding parts throughout the several views. Further, as used herein, the words “a,” “an” and the like generally carry a meaning of “one or more,” unless stated otherwise.

Furthermore, the terms “approximately,” “approximate,” “about,” and similar terms generally refer to ranges that include the identified value within a margin of 20%, 10%, or preferably 5%, and any values therebetween.

As used herein, the term “electrode” refers to an electrical conductor used to contact a non-metallic part of a circuit e.g., a semiconductor, an electrolyte, a vacuum, or air.

As used herein, the term “substrate” refers to an underlying layer that supports the primary layer.

As used herein, the term “nanobeads” refers to composites of nanoparticles. Nanoparticles are particles that have at least one dimension in the range less than 100 nanometers (nm), while nanobeads are usually around 50 to 200 nanometers in diameter.

As used herein, the term “current density” refers to the amount of electric current traveling per unit cross-section area.

As used herein, the term “Tafel slope” refers to the relationship between the overpotential and the logarithmic current density.

As used herein, the term “aerosolizing” refers to a process of intentionally oxidatively converting solution for the purpose of delivering the oxidized aerosols to the heating chamber.

As used herein, the term “aerosol” refers to extremely small solid particles, or very small liquid droplets, suspended in the atmosphere.

As used herein, the term “electrochemical cell” refers to a device capable of either generating electrical energy from chemical reactions or using electrical energy to cause chemical reactions.

As used herein, the term “water splitting” refers to the chemical reaction in which water is broken down into oxygen and hydrogen.

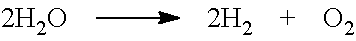

Embodiments of the present disclosure are directed to a vanadium oxide (VOₓ)-based electrocatalysts for electrochemical water splitting reactions.

According to an aspect of the present disclosure, an electrode is described. The electrode includes a metallic substrate onto which is disposed, at least partially, a layer of particles of vanadium oxide composite covering a surface of the metallic substrate. In some embodiments, at least 50% of the surface of the metallic substrate is covered by the vanadium oxide composite based on a total surface area of the metallic substrate, preferably at least 70%, preferably at least 90%, or even more preferably at least 99%, based on the total surface area of the metallic substrate. In another embodiment, only one side of the metallic substrate is covered with the vanadium oxide composite.

In some embodiments, the metallic substrate is at least one metal foam selected from the group consisting of an aluminum foam, a nickel foam, a titanium foam, a titanium alloy foam, an aluminum alloy foam, a magnesium alloy foam, a nickel alloy foam, and a steel foam. Optionally, the substrate may include other particles of Au, Ag, Pt, Pd, Co, Rh, Ru, Mn, Cr, Mo, Re, W, Ta, Nb, V, Hf, Zr, Ti, Al, and/or alloys thereof. In a preferred embodiment, the metallic substrate may be a nickel foam (NiF) and a nickel alloy foam. The NiF substrate may optionally include metals in addition to nickel, such as iron, aluminum, or alloys thereof. In some embodiments, the NiF substrate is a porous material. In an embodiment, the average pore size of the NiF substrate is about 50 to 500 micrometers (μm), preferably 100 to 450 μm, preferably 150 to 400 μm, preferably 200 to 350 μm, preferably 250 to 300 μm, or even more preferably about 300 μm. Other ranges are also possible. In some further embodiments, the NiF substrate may be of any shapes, such as cubical, conical, cuboidal, pyramidical, or cylindrical. In an embodiment, the pores of the NiF substrate have a spherical shape. In some embodiments, the substrate may be a glass substrate.

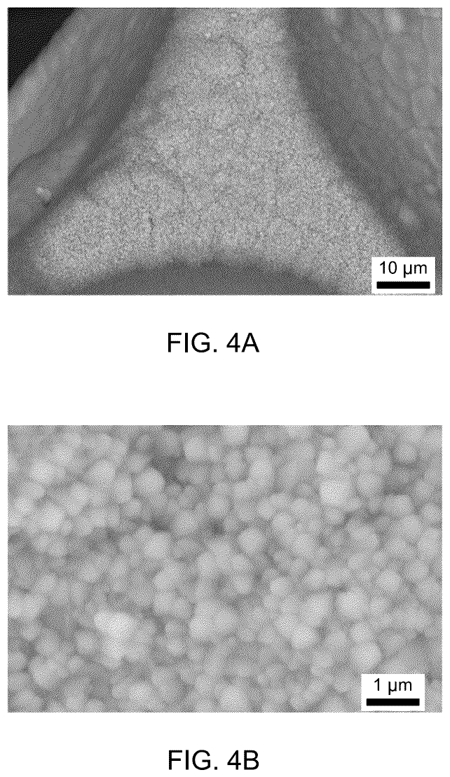

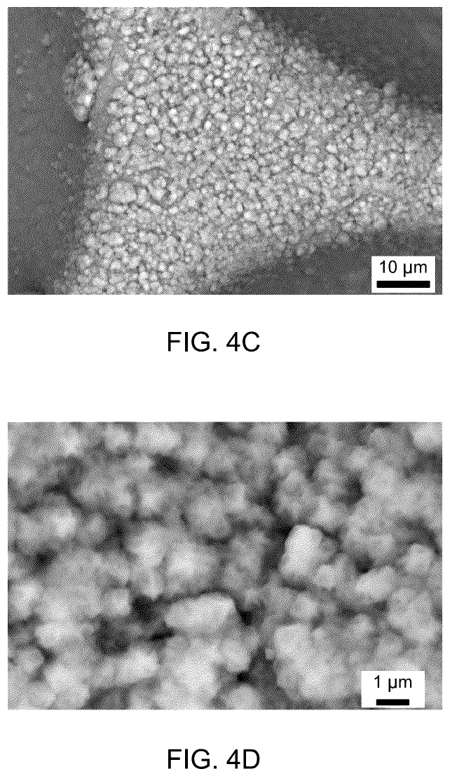

The electrode further includes a vanadium oxide composite that at least partially covers the surface of the metallic substrate. It is preferred that the vanadium oxide composite forms a uniform layer that completely covers the surface of the substrate. In some embodiments, the vanadium nanocomposite includes particles in the form of nanobeads. In some embodiments, the vanadium nanocomposite may exist in any other morphological form such as nanorods, nanotubes, nanospheres, nanosheets, and/or combinations thereof. In some further embodiments, the nanobeads may have an average particle size of 50 to 400 nm, preferably between 100 to 300 nm, preferably 150 to 250 nm, and most preferably between 100 to 200 nm. Other ranges are also possible. In some preferred embodiments, the nanoscale vanadium oxide particles may accumulate on the surface of the metallic substrate to form micro-sized aggerates in any irregular shape, as depicted in FIG. 4C.

In some embodiments, the vanadium oxide composite may include vanadium in several oxidation states, such as +2, +3, +4, and +5. The vanadium oxide composite may include various oxides of vanadium such as vanadium monoxide (VO), vanadium trioxide (V₂O₃), vanadium dioxide (VO₂), and vanadium pentoxide (V₂O₅). In some further embodiments, the vanadium oxide composite may be VO and VO₂ phases. Other states may also exist. The existence of such states is dependent on the choice of the precursor used to prepare the vanadium oxide composite. For example, the use of vanadium (III) acetylacetonate (V(acac)₃) as a vanadium oxide composite produces vanadium oxide in the form of V₂O₃.

In one embodiment, the metallic substrate is a nickel foam. In a preferred embodiment, a combination of the vanadium oxide composite and the nickel foam has a synergistic effect, resulting in improved electrocatalytic performance of the electrode.

The electrode of the present disclosure has a current density of 800 to 1200 mA/cm², preferably about 800 to 1000 mA/cm², or about 900 mA/cm², at a potential of 1.7 V_{RHE}. Other ranges are also possible. One of the indicators that access the OER kinetics is the Tafel slope. The Tafel slope shows how efficiently an electrode can produce current in response to a change in applied potential. Therefore, a low Tafel slope may indicate that less overpotential is required to get a high current. In some embodiments, the electrode has a Tafel slope of 50 to 90 mV/decade, preferably 60-80 mv/decade, and most preferably 68-70 mV/decade, which is lower than the metallic substrate without the vanadium oxide composite layer, therefore the electrode of the present disclosure may facilitate the energy-intensive step during the OER process.

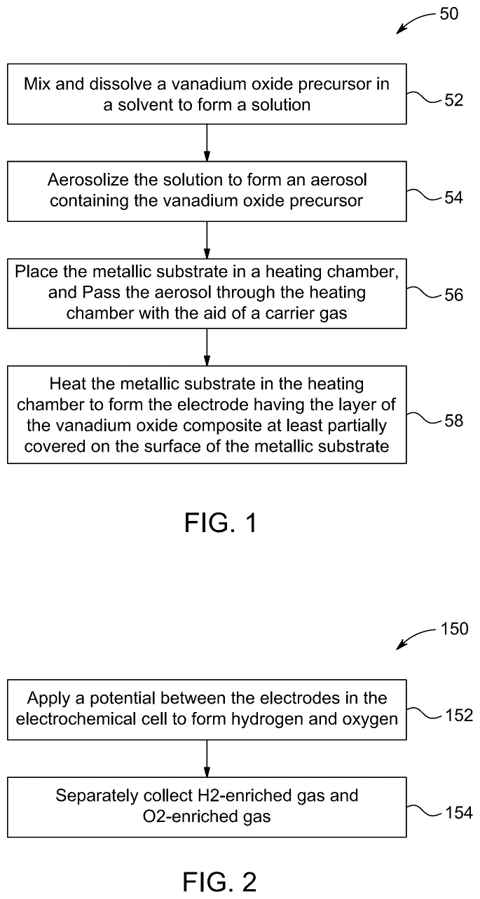

In an exemplary embodiment, a method of making the electrode is described. Referring to FIG. 1, a schematic flow diagram of a method of making the electrode is illustrated. The order in which the method 50 is described is not intended to be construed as a limitation, and any number of the described method steps may be combined in any order to implement the method 50. Additionally, individual steps may be removed or skipped from the method 50 without departing from the spirit and scope of the present disclosure.

At step 52, the method 50 includes mixing and dissolving a vanadium oxide precursor in a solvent to form a solution. In some embodiments, the vanadium oxide precursor is at least one selected from the group consisting of ammonium vanadate (NH₄VO₃), vanadyl oxalate (C₂H₂O₅V), vanadium pentoxide (V₂O₅), vanadium monoethanolamine (C₂H₇NOV), vanadium chloride (VCl₃), vanadium trichloride oxide (VOCl₃), vanadyl sulfate (VOSO₄), vanadium antimonate (O20Sb5V3-15), antimony vanadate (NH₄VO₃), vanadium oxyacetylacetonate (C₁₀H₁₆O₅V), vanadium oxyacetate (C4H8O5V), vanadium oxyhalide (X₂OV; where X=chlorine (Cl), fluorine (F) bromine (Br) and iodine (I)), and vanadium oxytriisopropoxide (C₉H₂₄O₄V). In a preferred embodiment, the vanadium oxide precursor is vanadium(IV) oxyacetylacetonate (VO(acac)₂). Optionally, a combination of vanadium oxide precursors may be dissolved in a solvent to form the solution at an appropriate concentration.

The solvent is at least one selected from the group consisting of a ketone solvent, an ester solvent, an alcohol solvent, an amide solvent, and an ether solvent. In some embodiments, the solvent is the alcohol solvent. In some embodiment, the alcohol solvent is at least one selected from the group consisting of methanol, ethanol, n-propanol, and isopropanol. The dissolution may be conducted manually or with the help of a stirrer. It is conducted till the vanadium oxide precursor is fully dissolved in the solvent, e.g., methanol, to form a solution. In some embodiments, the vanadium oxide precursor is present in the solution at a concentration of 0.01 to 0.1 M. In some further embodiments, the vanadium oxide precursor is present in the solution at a concentration of higher than 0.1 M. Other ranges are also possible.

At step 54, the method 50 includes aerosolizing the solution to form an aerosol containing the vanadium oxide precursor. The aerosolizing is achieved by AACVD process. The AACVD process involves atomizing a precursor solution into fine, sub-micrometer-sized aerosol droplets, which are delivered to a heated reaction zone and undergo evaporation, decomposition, and homogeneous and/or heterogeneous chemical reactions to form the desired products. Using the AACVD route, a batch of films with different thicknesses and morphologies can be fabricated. This can be achieved by controlling parameters, such as deposition temperature, deposition time, gas carrier flow rate, precursor, and concentration of the precursor solution, etc. In some embodiments, the aerosolizing may be conducted at a temperature of 300 to 600° C., preferably 350 to 550° C., preferably about 400 to 500° C., or even more preferably about 470° C., for a period of time in a range of 5 to 180 minutes, preferably 10 to 150 minutes, preferably 15 to 120 minutes, preferably 20 to 90 minutes, preferably about 25 to 60 minutes, or even more preferably about 30 to 60 minutes. Other ranges are also possible. The aerosolizing process may be performed on an aerosol generator. Many different types of aerosol generators are known and may be used depending on the film desired.

In some embodiments, the aerosol generator includes a fluid chamber and a heating chamber. The fluid chamber includes a plurality of openings to allow for the entry and exit of the fluids. In an embodiment, the fluid chamber includes one or more housing inlets. The solution to be aerosolized is introduced into the fluid chamber via the housing inlet. In some embodiments, the solution can be introduced through one inlet, or through a plurality of inlets, where each inlet from among the plurality of inlets leads to the fluid chamber. The fluid chamber is fluidly connected to a vibrating element operably coupled to a support plate. In an embodiment, the vibrating element is an ultrasonic device, such as an ultrasonic humidifier or an ultrasonic atomizer. The ultrasonic humidifier is configured to generate an aerosol from the solution containing the vanadium oxide precursor. The fluid chamber further includes a vent through which is introduced a carrier gas. Suitable examples of carrier gas include H₂, Ar, N₂, or a combination thereof. In a preferred embodiment, the carrier gas is nitrogen. The fluid chamber further includes a housing outlet that fluidly connects the fluid chamber and a heating chamber.

At step 56, the method 50 includes placing a metallic substrate in a heating chamber and passing the aerosol through the heating chamber with the aid of a carrier gas. In some embodiments, the carrier gas transports the aerosol from the fluid chamber to the heating chamber via the housing outlet. In some further embodiments, the carrier gas may be used to transport the aerosol over long distances (tens to hundreds of meters), which causes some aerosol loss and a change in its size distribution. In some more embodiments, the aerosol is passed through the heating chamber at a rate of 80 to 120 cm³/min, preferably 90-110 cm³/min, and most preferably 100 cm³/min. Other ranges are also possible.

At step 58, the method 50 includes heating the metallic substrate in the heating chamber to form the electrode having the layer of the vanadium oxide composite at least partially covered on a surface of the metallic substrate. The heating chamber is maintained at a temperature range of 400 to 600° C., preferably 420-580° C., preferably 450 to 550° C., preferably 400-500° C., more preferably to about 470° C. Other ranges are also possible. The heating chamber is configured such that the metallic substrate is in direct contact with the aerosol. At this temperature, the solvent from the aerosol evaporates, leaving behind the precursor. At least a portion of the vanadium oxide precursor is decomposed to generate the vanadium oxide composite. In some embodiments, at least 50% of the vanadium oxide precursor is decomposed to generate the vanadium oxide composite based on an initial number of the vanadium oxide precursor molecules introduced into the heating chamber, preferably at least 60%, preferably at least 70%, preferably at least 80%, preferably at least 90%, or even more preferably at least 99% based on the initial number of the vanadium oxide precursor molecules introduced into the heating chamber. Other ranges are also possible. The vanadium oxide composite is further deposited on the substrate to obtain the electrode. The thickness of the vanadium oxide composite on the substrate depends on how long the deposition process takes place. In an embodiment, the deposition process is conducted for a period of 0.25-2 hours, preferably 0.5-1 hour, to obtain the electrode. Other ranges are also possible.

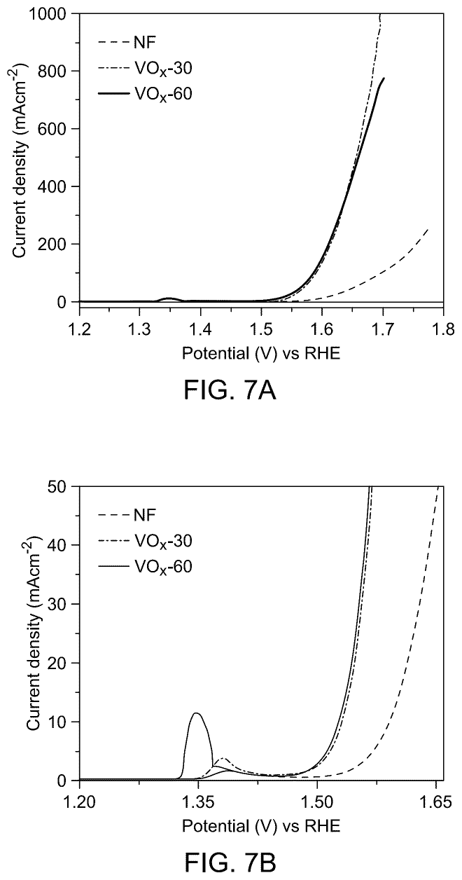

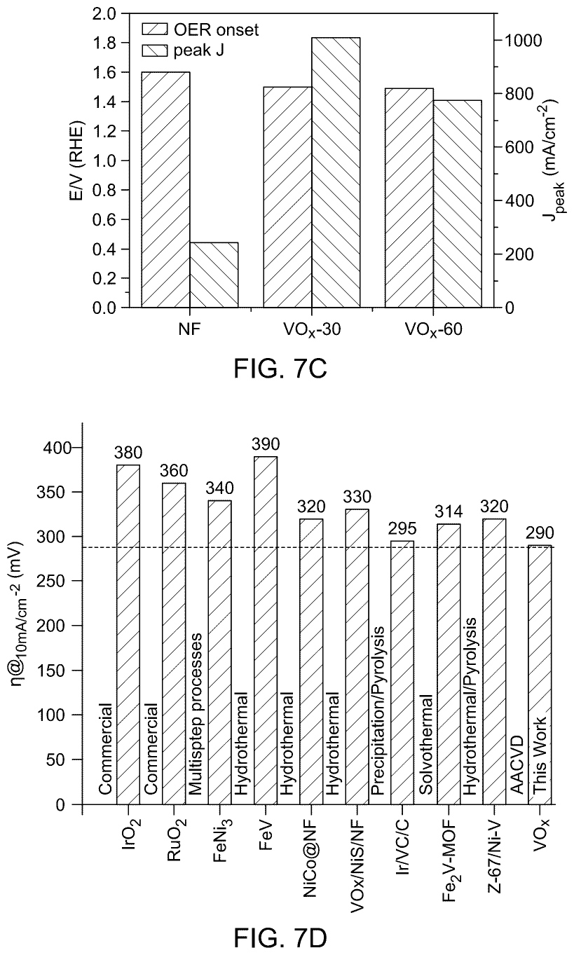

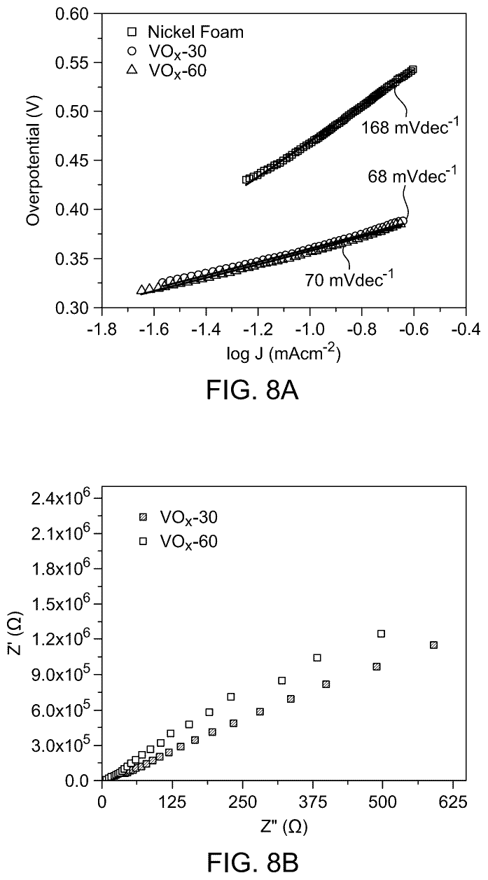

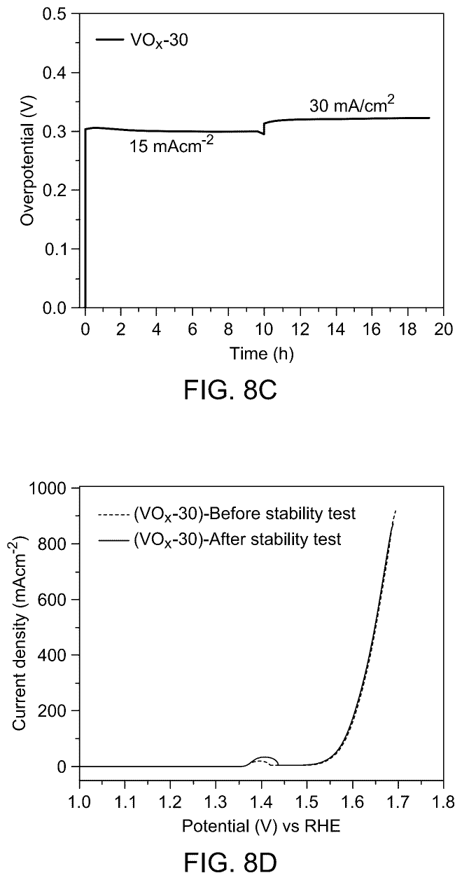

In one embodiment, the vanadium oxide nanocomposite was deposited on the nickel foam substrate to form the electrode referred to as VOₓ-30, under AACVD conditions having a temperature of about 470° C., a deposition time of 30 minutes, using a solution containing methanol and vanadium(IV) oxyacetylacetonate (VO(acac)₂), and the carrier gas is N₂ gas. In one preferred embodiment, the vanadium oxide nanocomposite was deposited on the nickel foam substrate to form the electrode referred to as VOₓ-60, under AACVD conditions having a temperature of about 470° C., a deposition time of 60 minutes, using a solution containing methanol and vanadium(IV) oxyacetylacetonate (VO(acac)₂), and the carrier gas is N₂ gas. In some embodiments, the electrodes VOₓ-30, and VOₓ-60 were evaluated in alkaline media, respectively. In some embodiments, the developed VOₓ catalyst deposited for 30 minutes (min) requires an overpotential of about 250 to 330 millivolts (mV), preferably about 290 mV, to reach a current decade of about 5 to 15 milliamperes per square centimeters (mAcm⁻²), preferably about 10 mAcm⁻² and reaches to a current density of 800 to 1200 mAcm⁻², preferably about 1000 mAcm⁻² at an overpotential of about 470 mV. The VOₓ-30 electrode has an OER with a current density of 1000 mAcm⁻² at 1.7 V (η=470 mV) Vs. a reversible hydrogen electrode (RHE), as depicted in FIG. 7C. Other ranges are also possible. In some further embodiments, the VOₓ-30 electrode has a Tafel slope of 68 millivolts per decade (mV/dec), as depicted in FIG. 8A. Other ranges are also possible. In addition, the VOₓ-30 electrode has a long-term durability by maintaining its initial current density after 19 hours of continuous exposure as depicted in FIG. 8C, thus outperforming several benchmark OER catalysts, such as iridium oxide (IrO₂), nickel oxide (NiO) and cobalt oxide (CoO), studied under similar conditions. The behavior of the VOₓ-30 electrode may be ascribed to nanoscale morphological features and synergistic effects of vanadium (V) based catalysts with underlying conductive nickel support.

The crystalline structures of the vanadium oxide nanocomposite may be characterized by X-ray diffraction (XRD), respectively. In some embodiments, the XRD patterns are collected in a Rigaku diffractometer equipped with a Cu-Kα radiation source (λ=0.15406 nm) for a 20 range extending between 5 and 90°, preferably 15 and 80°, further preferably 30 and 60° at an angular rate of 0.005 to 0.04° s⁻¹, preferably 0.01 to 0.03° s⁻¹, or even preferably 0.02° s⁻¹.

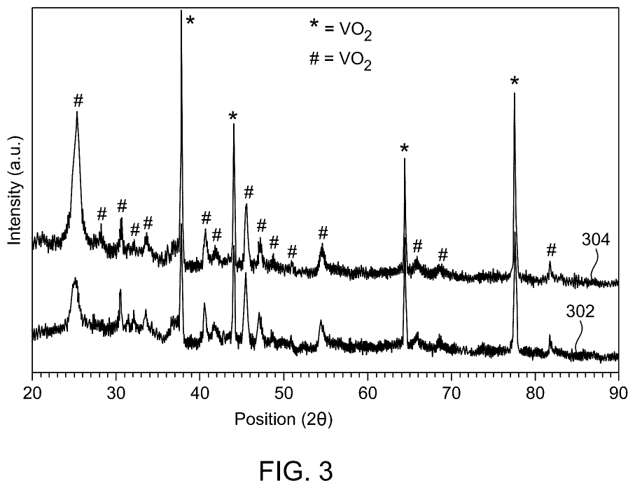

An X-ray diffraction (XRD) pattern of the vanadium oxide nanocomposite (VOₓ) deposited on a non-crystalline plain glass substrate is illustrated in FIG. 3. In some embodiments, the X-ray spectrum of the vanadium oxide nanocomposite deposited for 30 (302) minutes and 60 minutes (304) has a VO phase and a VO₂ phase as depicted in FIG. 3. In some further embodiments, the VO phase has a first intense peak with a 2 theta (0) value in a range of 35 to 41° in the XRD spectrum, preferably about 37.8° corresponding to the reflection plane (111); a second intense peak with a 20 in a range of 41 to 47°, preferably about 43° corresponding to the reflection plane (200); a third intense peak with a 20 in a range of 61 to 67°, preferably about 63° corresponding to the reflection plane (220); and a fourth intense peak with a 20 in a range of 74 to 80°, preferably about 76.8° corresponding to the reflection plane (311), as depicted in FIG. 3. In some preferred embodiments, the VO₂ phase has a first intense peak with a 2 theta (0) value in a range of 23 to 26.3° in the XRD spectrum, preferably about 25.3° corresponding to the reflection plane (110); a second intense peak with a 20 in a range of 27 to 30°, preferably about 28.9° corresponding to the reflection plane (−202); a third intense peak with a 20 in a range of 29 to 32°, preferably about 30.3° corresponding to the reflection plane (002); a fourth intense peak with a 20 in a range of 31 to 36°, preferably about 33.6° corresponding to the reflection plane (310); a fifth intense peak with a 20 in a range of 39 to 43°, preferably about 41° corresponding to the reflection plane (112); a sixth intense peak with a 20 in a range of 43 to 45°, preferably about 45° corresponding to the reflection plane (−601); a seventh intense peak with a 20 in a range of 45 to 46°, preferably about 45.3° corresponding to the reflection plane (003); an eighth intense peak with a 20 in a range of 46 to 48°, preferably about 47.2° corresponding to the reflection plane (600); a ninth intense peak with a 20 in a range of 48 to 51°, preferably about 49° corresponding to the reflection plane (020); a tenth ninth intense peak with a 20 in a range of 52 to 55°, preferably about 54.4° corresponding to the reflection plane (113); an eleventh intense peak with a 20 in a range of 54 to 58°, preferably about 55.2° corresponding to the reflection plane (−603); a twelfth intense peak with a 20 in a range of 62 to 70°, preferably about 66° corresponding to the reflection plane (−604); and a thirteenth intense peak with a 20 in a range of 78 to 86°, preferably about 81.7° corresponding to the reflection plane (−331), as depicted in FIG. 3. Other ranges are also possible.

The electrode thus prepared by the method of the present disclosure forms the working electrode in an electrochemical cell. The electrochemical cell further includes a reference electrode and a counter electrode. In a preferred embodiment, the reference electrode is Ag/AgCl, and the counter electrode is a Pt wire.

Referring to FIG. 2, a schematic flow diagram of a method for electrochemical water splitting reaction is described. The electrode of the present disclosure can be used for electrochemical water splitting reaction. The order in which the method 150 is described is not intended to be construed as a limitation, and any number of the described method steps may be combined in any order to implement the method 150. Additionally, individual steps may be removed or skipped from the method 150 without departing from the spirit and scope of the present disclosure.

At step 152, the method 150 includes applying a potential between the electrodes in the electrochemical cell to form hydrogen and oxygen. During the electrochemical process, a potential of 0.0 to 1.0 V is applied to the working electrode, and the counter electrode that are immersed in an aqueous electrolyte solution. The counter electrode forms the auxiliary electrode. The outer surface of the counter electrode includes an inert, electrically conducting chemical substance, such as platinum, gold, or carbon. The carbon may be in the form of graphite or glassy carbon. In a preferred embodiment, the counter electrode is a Pt wire. In one embodiment, the counter electrode may be a wire, a rod, a cylinder, a tube, a scroll, a sheet, a piece of foil, a woven mesh, a perforated sheet, or a brush. The counter electrode material should thus be sufficiently inert to withstand the chemical conditions in the electrolyte solution, such as acidic or basic pH values, without substantially degrading during the electrochemical reaction. The counter electrode preferably should not leach out any chemical substance that interferes with the electrochemical reaction or might lead to undesirable. The aqueous electrolyte solution includes an aqueous solution of a base (base and an aqueous solution). The base selected from the group consisting of an alkaline earth metal hydroxide such as beryllium hydroxide (Be(OH)₂), magnesium hydroxide (Mg(OH)₂), strontium hydroxide (Sr(OH)₂), and calcium hydroxide (Ca(OH)₂) and an alkali metal hydroxide such as lithium hydroxide (LiOH), sodium hydroxide (NaOH), potassium hydroxide (KOH) and rubidium hydroxide (RbOH), and cesium hydroxide (CsOH). In a preferred embodiment, the base is potassium hydroxide. The concentration of the base may lie in a range of about 0.1 molar (M) to 3 M, more preferably 0.5-2.5 M, and yet more preferably of about 1.0 M. Other ranges are also possible. In some embodiments, the electrolyte solution was deoxygenated aqueous electrolyte solution at room temperature (RT).

In some embodiments, the working electrode and the counter-electrode are connected to each other by way of electrical interconnects that allow for the passage of current between the electrodes, when a potential is applied between them. In a preferred embodiment, the electrocatalyst (which forms the working electrode) and the counter electrode are at least partially submerged in the water and are not in physical contact with each other. In an embodiment, the working electrode and the counter-electrode can have the same or different dimensions. In certain embodiments, the working electrode has a cross-section diameter of about 1.68 mm, and the counter-electrode as a cross-section diameter of about 0.2 mm. The working electrode and the counter-electrode may be arranged as obvious to a person of ordinary skill in the art.

At step 154, the method 150 includes the electrochemical process resulting in formation of hydrogen and oxygen. The H₂-enriched gas is collected at the cathode, and the O₂-enriched gas is collected at the anode.

### EXAMPLES

The following examples demonstrate the catalytic activity of an electrocatalyst, including a vanadium oxide (VOₓ) layering on an electrode, using the AACVD deposition for electrochemical water splitting, as described herein. The examples are provided solely for illustration and are not to be construed as limitations of the present disclosure, as many variations thereof are possible without departing from the spirit and scope of the present disclosure.

### Example 1: Materials and Substrate

All chemicals, vanadium(IV) oxyacetylacetonate (VO(acac)₂, 98%), methanol anhydrous (99.8%), and material, nickel foam (NiF), were obtained from Sigma-Aldrich.

### Example 2: Fabrication of Vanadium Oxide (VOₓ) Thin Film

A self-designed AACVD setup was employed for thin film deposition. AACVD is a modified version of chemical vapor deposition (CVD), which requires a fully dissolved precursor in solution. Here, the required amount of VO(acac)₂ was dissolved in 15 milliliters (mL) of methanol and was employed in AACVD to deposit a VOₓ thin film on a porous NiF substrate (dimension=1×2 cm²). The deposition was conducted for two different periods-30 and 60 min and at a fixed temperature of 470° C. for each case. The AACVD process involves the generation of precursor aerosol mist using an ultrasonic humidifier and driven towards a horizontal tube furnace with help of carrier gas (industrial nitrogen (N₂, 99.9%)) at a flow rate of 100 cm³/min. The temperature of a tube furnace was set at 470° C., and the NiF substrates were placed inside the tube to receive the aerosol mist directly over it, where the decomposition of precursor occurs to generate the thin film. The process of AACVD was continued for 30 and 60 minutes and deposited samples were labeled as VOₓ/NiF-30 and VOₓ/NiF-60, respectively.

### Example 3: Physical Characterization of Catalytic Thin Films

The crystalline patterns of VOₓ thin films were studied by an X-ray diffractometer (XRD) using a benchtop Rigaku MiniFlex. Surface morphologies of the VOₓ films were analyzed using a scanning electron microscope (SEM) JEOL JSM-6460. An X-ray photoelectron spectroscopy (XPS) was used to study the oxidation states of the major elements of the thin film, i.e., vanadium (V) and oxygen (O) using a Thermo Scientific Escalab 250Xi spectrometer. Obtained Spectra were corrected with reference to the adventitious C 1 s peak at 284.8 electro Volts (eV).

### Example 4: Investigation of Electrochemical Properties

In a typical setup, a three-electrode cell (VOₓ/NiF working, silver (Ag)/silver chloride (AgCl) reference electrode and platinum (Pt) wire counter electrode) was used to study the electrochemical oxidation of water molecules using aqueous 1.0 Molarity (M) potassium hydroxide (KOH) as electrolyte at room temperature (RT). Potentiostat INTERFACE 1010 E was used to record the data. The electrolyte solution was deoxygenated aqueous electrolyte solution at room temperature (RT). All electrochemical data were presented with 10% infrared (IR) correction. The polarization curves were recorded by linear sweep voltammetry (LSV) at a scan rate of 5 millivolts per second (mV/s).

According to the Nernst equation, all the potentials here are converted into reversible hydrogen electrodes (RHE).

$${E}_{R H B} = {E}_{R E F} + {E}_{REF}^{0} + 0.059 ( pH )$$

Overpotential is calculated according to the following equation

$$Overpotential ( η ) = {E}_{RHE} - 1.23$$

Tafel slopes are calculated from the linear region of the polarization curve where the Tafel region begins using a Tafel equation.

$$η = b log j + a$$

where b is a Tafel slope, and a is constant.

### Example 5: Structural Morphology

Crystalline VOₓ thin films were deposited on the NiF using the AACVD process at atmospheric pressure. XRD investigated the crystalline structure of the VOx film. The XRD pattern of VOₓ was hindered due to the higher crystallinity of the NiF substrate, and nickel peaks were obtained in the XRD patterns. Therefore, VOₓ films were prepared on a non-crystalline plain glass substrate under identical AACVD conditions to examine the real deposited phase and crystalline structure of these samples. FIG. 3 shows the overlaid XRDs of both film samples deposited for 30 (302) and 60 minutes (304). VO phase is determined from the crystalline peaks that appeared at 2θ=37.8°, 44°, 64° and 76.8° produced from reflection planes (111), (200), (220), and (311), respectively. The XRD data is in accordance with standard cubic phased vanadium (II) oxide of chemical formula “VO” ICSD card No. 28681. The XRD peaks of VO are labeled with a symbol (*). VO₂ phase is determined by the distinct crystalline peaks that emerged at 20 position from the corresponding (hkl) planes are as follows; 25.3° (110), 28.9° (−202), 30.3° (002), 33.6° (310), 41° (112), 45° (−601), 45.3° (003), 47.2° (600), 49° (020), 54.4° (113), 55.2° (−603), 66° (−604) and 81.7° (−331) and are indicated by the symbol (#). The XRD pattern of the VO₂ phase corresponds to standard “vanadium (IV) oxide” VO₂ 73856(ICSD) [Oka, Y.; Yao, T.; Yamamoto, N.; Ueda, Y.; Hayashi, A., Phase transition and V4+-V4+ pairing in VO₂ (B). Journal of Solid State Chemistry 1993, 105 (1), 271-278, incorporated herein by reference in its entirety]. In both samples, both VO and VO₂ phases co-exist, as observed from their superimposed peaks patterns shown in FIG. 3, while pure VO₂ thin films were claimed while using (VO(acac)₂) precursor in a mist chemical vapor deposition (CVD) setup at relatively high temperatures of 650° C. [Matamura, Y.; Ikenoue, T.; Miyake, M.; Hirato, T., Mist CVD of vanadium dioxide thin films with excellent thermochromic properties using a water-based precursor solution. Solar Energy Materials and Solar Cells 2021, 230, 111287, incorporated herein by reference in its entirety]. For CVD-based techniques, precursor, temperature, and solvents are the key factors that decide the crystal phase and physical properties of the resulting films [Ehsan, M. A.; Ming, H. N.; Misran, M.; Arifin, Z.; Tiekink, E. R.; Safwan, A. P.; Ebadi, M.; Basirun, W. J.; Mazhar, M., Effect of AACVD Processing Parameters on the Growth of Greenockite (CdS) Thin Films using a Single-Source Cadmium Precursor. Chemical Vapor Deposition 2012, 18 (7-9), 191-200, incorporated herein by reference in its entirety]. The use of precursor vanadium (III) acetylacetonate (V(acac)₃) resulted in the formation of V₂O₃ thin films [Piccirillo, C.; Binions, R.; Parkin, I. P., Synthesis and functional properties of vanadium oxides: V2O3, VO2, and V2O5 deposited on glass by aerosol-assisted CVD. Chemical Vapor Deposition 2007, 13 (4), 145-151, incorporated herein by reference in its entirety]. The V₂O₃ phase can be further oxidized by introducing water vapors in the reaction, and a stable VO₂ phase was produced [Ren, H.; Li, B.; Zhou, X.; Chen, S.; Li, Y.; Hu, C.; Tian, J.; Zhang, G.; Pan, Y.; Zou, C., Wafer-size VO₂ film prepared by water-vapor oxidant. Applied Surface Science 2020, 525, 146642, incorporated herein by reference in its entirety].

FIGS. 4A and 4B illustrate the morphological attributes of VOₓ deposited on the NiF substrate, as examined by field emission scanning electron microscopy (FESEM). FIG. 4C illustrates a high magnification image indicating the formation of interconnected nanobeads of size ranging from 100-200 nm. Further, FIG. 4D shows the image when the deposition time was increased to 60 minutes, the deposited layer became dense, and a clear film was observed even at the low magnification micrograph. The attribution of increased deposition time and sintering effect became noticeable on the surface of the particles, and nanoparticles grew submicron-sized due to the coagulation with each other. Coagulation refers to an improvement in the sinterability of the nanoparticles and prominent defects and voids between the sintered submicron particles. The morphological transition from nanoscale particles to microsized objects of irregular shape within just one hour was found to be promising for OER investigations.

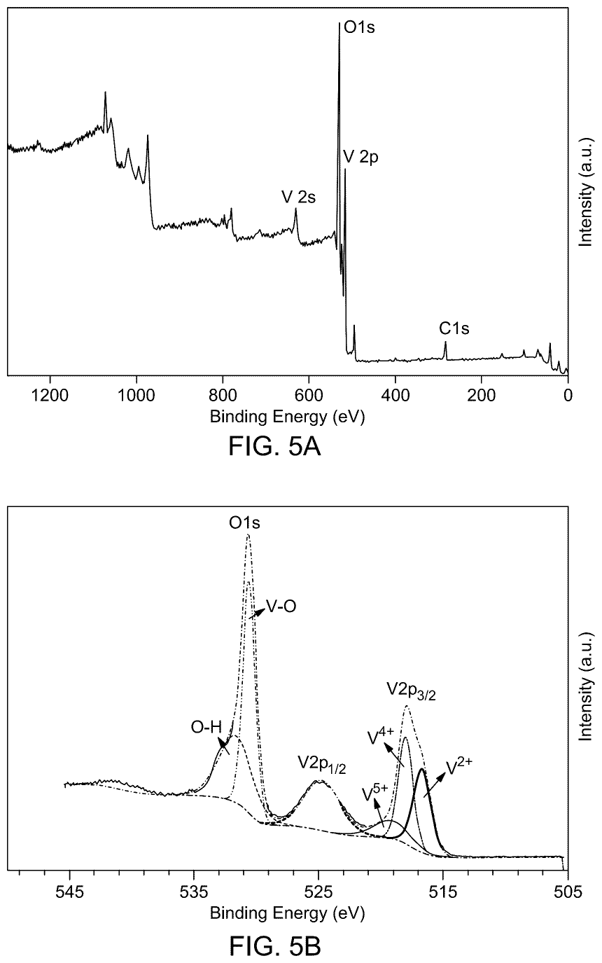

Further, the chemical states of V and O elements within the VOₓ-30 thin film sample were analyzed by XPS, and the results of this study are shown in FIG. 5A. FIG. 5B shows the survey spectrum and the high-resolution deconvoluted spectrum of the Ols and V2p regions. V2p spectrum showed two peaks at binding energies at 517.9 eV and 524.7 eV, corresponding to the P V2p_{3/2} and V2p_{3/2}, respectively. The V2p_{3/2} peak was split into two binding energy peaks at 516.4 eV and 518.4 eV referring to the V²⁺ and V⁴⁺ oxidation states, respectively. The binding energy values were slightly higher than those reported for VO and VO₂ phases, which might be attributed to the smaller crystal sizes of the synthesized oxide [Silversmit, G.; Depla, D.; Poelman, H.; Marin, G. B.; De Gryse, R., Determination of the V2p XPS binding energies for different vanadium oxidation states (V5+ to V0+). Journal of Electron Spectroscopy and Related Phenomena 2004, 135 (2-3), 167-175, incorporated herein by reference in its entirety]. A short peak at 519. 7 eV indicated the presence of high valent V⁵⁺ as well [Mendialdua, J.; Casanova, R.; Barbaux, Y., XPS studies of V₂O₅, V₆O₁₃, VO₂ and V₂O₃. Journal of Electron Spectroscopy and Related Phenomena 1995, 71 (3), 249-261, incorporated herein by reference in its entirety]. The Ols spectrum at 530.6 eV was also divided into two peaks around 530.3 eV and 532. 2 eV, which were assigned to the V-O bond involved in VOₓ and hydroxyl oxygen (O—H) adsorbed from the environment, respectively [Kumar, A. M.; Ehsan, M. A.; Suleiman, R. K.; Hakeem, A. S., AACVD processed binary amorphous NiVOx coatings on Cu substrates: Surface characterization and corrosion resistant performance in saline medium. Colloids and Surfaces A: Physicochemical and Engineering Aspects 2022, 633, 127893, incorporated herein by reference in its entirety].

### Example 6: Electrochemical Studies

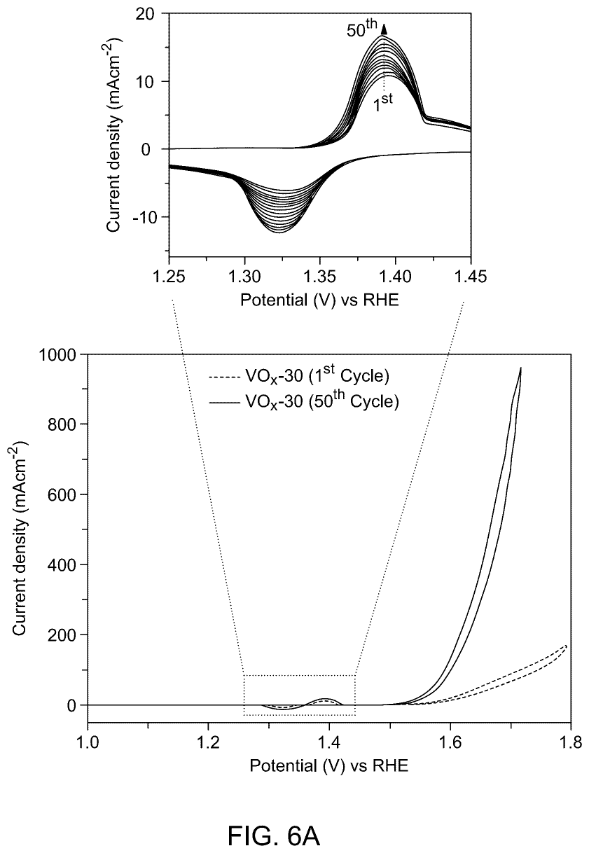

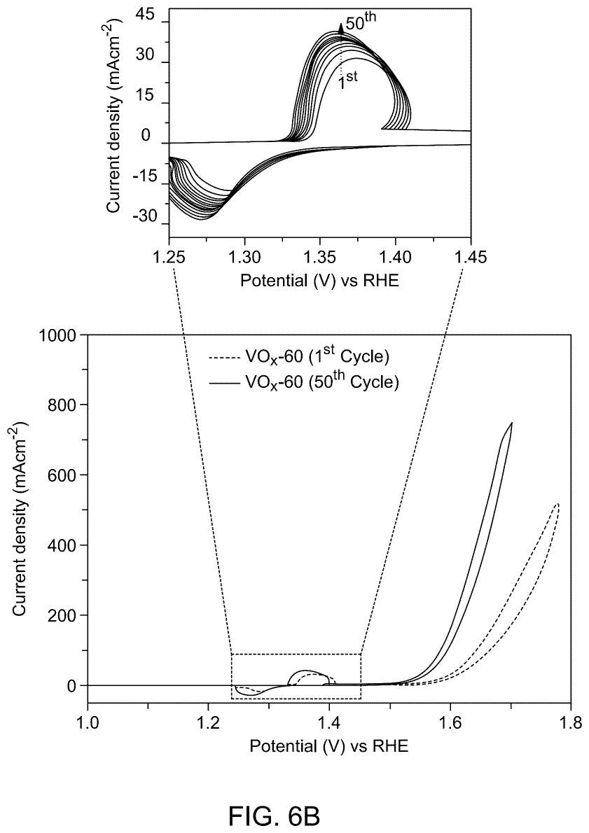

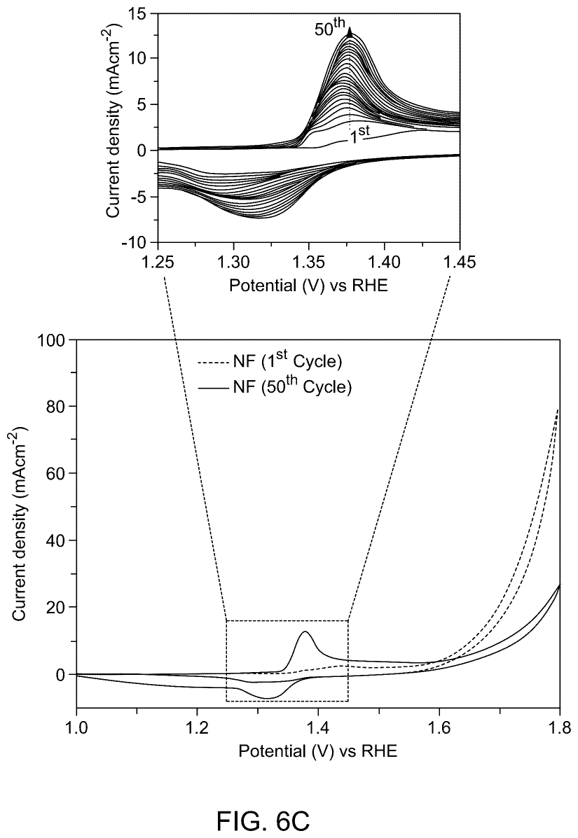

VOX/NiF thin film electrocatalyst was directly employed to study the electrochemical oxidation of water molecules in a 1.0 M aqueous KOH electrolyte. The catalyst samples were cycled between 1.0 to 1.7 volts in a CV-based pre-activation process, and the results of this study are depicted in FIG. 6A and FIG. 6B, respectively. As a result of continuous CV runs, the 50th CV cycle exhibits a higher current density at a relatively lower potential compared to its 1st CV cycle (FIGS. 6A-6B). In FIG. 6C, the bare NiF was also subjected to an activation process under similar electrochemical conditions. Minor improvement in the current signal was observed compared to the VOx-deposited catalysts. The activation process creates redox species on the surface of the catalyst, which boosts the water oxidation reaction rates [Ehsan, M. A.; Khan, A.; Zafar, M. N.; Akber, U. A.; Hakeem, A. S.; Nazar, M. F., Aerosol-assisted chemical vapor deposition of nickel sulfide nanowires for electrochemical water oxidation. International Journal of Hydrogen Energy 2021, and Ehsan, M. A.; Rehman, A.; Afzal, A.; Ali, A.; Hakeem, A. S.; Akbar, U. A.; Iqbal, N., Highly Effective Electrochemical Water Oxidation by Millerite-Phased Nickel Sulfide Nanoflakes Fabricated on Ni Foam by Aerosol-Assisted Chemical Vapor Deposition. Energy & Fuels 2021, 35 (19), 16054-16064, each incorporated herein by reference in their entirety]. The reduction-oxidation peaks associated with each catalytic system were presented in the inset of the corresponding voltammogram in FIGS. 6A-6C, where the height of a redox peak increases with every CV.

After the initial activation of the catalysts, LSV was performed. It was observed that the VOₓ electrocatalyst derived the water oxidation reaction at low over potential and achieved high current densities under the small potential window, as shown in FIG. 7A. Electrocatalyst getting oxygen evolution below 1.55 V vs. RHE is considered as an OER electrocatalyst and was observed in the enlarged view shown in FIG. 7B [Babar, N.-U.-A.; Joya, K. S., Spray-Coated Thin-Film Ni-Oxide Nanoflakes as Single Electrocatalysts for Oxygen Evolution and Hydrogen Generation from Water Splitting. ACS omega 2020, 5 (19), 10641-10650, and Babar, N.-U.-A.; Hussain, F.; Ashiq, M. N.; Joya, K. S., Engineered Modular Design of a Nanoscale CoNP/Aunano Hybrid Assembly for High-Performance Overall Water Splitting. ACS Applied Energy Materials 2021, 4 (9), 8953-8968, each incorporated herein by reference in their entirety]. Here, both catalytic systems initiated the water oxidation reaction at 1.5 V vs. RHE and achieved a current decade (10 mAcm⁻²) at an overpotential (η10) of 290 mV vs. RHE. Under similar electrochemical conditions, the bare NiF indicated the current decade at a relatively higher potential of 1.6 V vs. RHE, which suggests that nanoscale VOₓ catalysts inherently have a lower potential than bare NiF. Furthermore, FIG. 7C illustrates the LSV profiles of both VOₓ/NiF-30 and VOₓ/NiF-60 showing a similar trend up to 1.6 V. At the same time, the VOX/NiF-30 reached a maximum current density of 1000 mA cm-2, and the maximum current density of VOₓ/NiF-60 stayed around 800 mAcm⁻² when compared at higher potential (1.7 V vs. RHE). This might be due to the microstructural differences found and discussed in the film patterns (FIG. 4). The VOₓ/NiF-30 manifests regularly interconnected nanoscale features while the voids and cavities seen in the microstructure of VOₓ/NiF-60 deteriorate its conductivity. A comparative OER response is shown in FIG. 7D, indicating the results of the work were comparable and better than some of the benchmarks in the field, such as Ruthenium (IV) oxide (RuO₂), Iridium (IV) oxide (IrO₂), and several other competent bimetallic systems [Samanta, R.; Panda, P.; Mishra, R.; Barman, S., IrO2-Modified RuO2 Nanowires/Nitrogen-Doped Carbon Composite for Effective Overall Water Splitting in All pH. Energy & Fuels 2022, 36 (2), 1015-1026, and da Silva, G. C.; Fernandes, M. R.; Ticianelli, E. A., Activity and stability of Pt/IrO2 bifunctional materials as catalysts for the oxygen evolution/reduction reactions. ACS Catalysis 2018, 8 (3), 2081-2092, each incorporated herein by reference in their entirety].

Tafel slope, which might be obtained from overpotential, and corresponding current density, is an important indicator to access the intrinsic catalytic kinetics of OER [Anantharaj, S.; Noda, S.; Driess, M.; Menezes, P. W., The Pitfalls of Using Potentiodynamic Polarization Curves for Tafel Analysis in Electrocatalytic Water Splitting. ACS Energy Letters 2021, 6 (4), 1607-1611, incorporated herein by reference in its entirety]. In FIG. 8A, the bare NiF showed a much higher Tafel value (168 mV/dec) as compared to the VOₓ catalysts (68 and 70 mV/dec, respectively, for the VOₓ/NiF-30 and VOₓ/NiF-60 samples), which means that as prepared electrode facilitates the energy-intensive step during the water oxidation reaction. Moreover, the Tafel values of both the VOₓ coincide, which reflects the comparable OER kinetics and equally competent behavior of both catalysts towards the water oxidation reaction. The is further confirmed by electrochemical impedance spectroscopy (EIS), where charge transfer resistance behavior is found to have a similar trend as shown in FIG. 8B. FIG. 8C shows the long-term stability of the electrode, which was a factor to investigate to support its applicability. The VOx-30 catalyst was investigated by controlled current electrolysis (CCE) experiments in 1.0 M aqueous KOH electrolyte solution to support applicability. Constant current densities of 15 and 30 mA/cm² were applied for a sufficiently long time while the output voltage response against these applied current densities was monitored. A steady overpotential (n) of just 0.3 V (1.53 V vs. RHE) was observed for the first ten (10) hours of the experiment at a fixed current density of just 15 mA/cm². Furthermore, the current density increased to 30 mA/cm², which was maintained with a mere enhancement of overpotential η=0.32 V (1.55 V vs. RHE). No noticeable change in potential and degradation of the catalytic activity was observed even after 19 hours of continuous electrolysis. The non-existence of change suggests the superior stability and high and stable catalytic activity of the catalyst for the water oxidation reaction. The LSV was measured soon after the long-term stability test, and the result of this study is presented in FIG. 8D. The LSV recorded after CCE overlaps the initial polarization curve of the VOₓ-30 recorded, further confirming the stability.

VOₓ catalytic films were deposited on the NiF substrate using the AACVD process and evaluated for the electrochemical water oxidation reaction in a 1.0 M KOH electrolyte. The nanoscale morphology of the VOₓ developed over conducting surface of the NiF helped accelerate the rate of oxidation reaction, and a current density of 10 mAcm⁻² was obtained at 1.52 V, while a high current density of 1000 Acm⁻² was achieved merely at 1.7 V vs. RHE. Moreover, the catalyst remained stable during nineteen (19) hours of continuous oxidation reaction monitoring without any apparent mechanical or chemical instability. This OER activity is improved compared to the existing OER representative catalysts, such as IrO₂, NiO, and CoO catalysts. It was further illustrated that the fabrication and successful exploitation of a simple transition metal-based electrocatalyst with outstanding OER performances would bring new promises for low-cost hydrogen production.

Numerous modifications and variations of the present disclosure are possible in light of the above teachings. It is therefore to be understood that within the scope of the appended claims, the invention may be practiced otherwise than as specifically described herein.

1. (canceled)

2. The method of claim 20, wherein the metallic substrate of the primary electrode is at least one metal foam selected from the group consisting of an aluminum foam, a nickel foam, a titanium foam, a titanium alloy foam, an aluminum alloy foam, a magnesium alloy foam, a nickel alloy foam, and a steel foam.

3. The method of claim 20, wherein the vanadium oxide composite of the primary electrode comprises vanadium monoxide (VO), vanadium trioxide (V₂O₃), vanadium dioxide (VO₂), and vanadium pentoxide (V₂O₅), and the metallic substrate is the nickel foam.

4. The method of claim 20, wherein the metallic substrate of the primary electrode is a nickel foam, and wherein a combination of the vanadium oxide composite and the nickel foam has a synergistic effect, resulting in improved electrocatalytic performance of the electrode.

5. The method of claim 20, wherein the primary electrode has a current density of 800 to 1200 mA/cm² at a potential of 1.7 V_{RHE}.

6. The method of claim 20, wherein the primary electrode has a Tafel slope of 50 to 90 millivolts per decade (mV/decade).

7-17. (canceled)

18. The method of claim 20, wherein the electrolyte comprises an aqueous solution of a base at a concentration of 0.1 to 3 M.

19. The method of claim 18, wherein the base is at least one selected from the group consisting of NaOH, KOH, LiOH, Ba(OH)₂, and Ca(OH)₂.

20. A method for electrochemical water splitting, comprising:
applying a potential between the electrodes in an electrochemical cell to form hydrogen and oxygen; and
separately collecting H₂-enriched gas and O₂-enriched gas,
wherein the electrochemical cell comprises:
a primary electrode;
a counter electrode; and
an electrolyte in contact with both electrodes,
wherein the primary electrode comprises:
a metallic substrate; and
a layer of particles of a vanadium oxide composite at least partially covering a surface of the metallic substrate;
wherein the particles of the vanadium oxide composite are in the form of nanobeads having an average particle size of 50 to 400 nm.
